(19) United States
(12) Patent Application Publication
(10) Pub. No.: US 2009/0147169 A1
(43) Pub. Date: Jun. 11, 2009

(54) THIN FILM TRANSISTOR AND LIQUID CRYSTAL DISPLAY INCLUDING THE SAME

(75) Inventors: Yong-Jo KIM, Gwangmyung-si (KR); Sang-Yong NO, Seoul (KR); Sung-Hoon KIM, Gwanak-gu (KR)

Correspondence Address: CANTOR COLBURN, LLP, 20 Church Street, 22nd Floor, Hartford, CT, 06103, US

(73) Assignee: Samsung Electronics Co., Ltd., Suwon-si (KR)

(21) Appl. No.: 12/331,810

(22) Filed: Dec. 10, 2008

(30) Foreign Application Priority Data
Dec. 11, 2007 (KR) 10-2007-0127965

(51) Int. Cl. G02F 1/1368; H01L 23/48

(52) U.S. Cl. 349/43; 257/288; 257/E23.01

(57) ABSTRACT

A thin film transistor and a liquid crystal display including the same include a gate electrode including an uneven pattern on at least one side defining the gate electrode, a source electrode partially overlapping the gate electrode, and a drain electrode separated from the source electrode and partially overlapping the gate electrode.

This application claims priority to Korean Patent Application No. 10-2007-0127965, filed on Dec. 11, 2007, and all the benefits accruing therefrom under 35 U.S.C. § 119, the contents of which in their entirety are herein incorporated by reference.

### BACKGROUND OF THE INVENTION

The present disclosure relates to a liquid crystal display (“LCD”), and more particularly, to a thin film transistor (“TFT”) configured to reduce light entrance into an active layer by forming an uneven pattern on at least one side of a gate electrode of the TFT.

An LCD, which is one type of various flat panel display devices, includes a lower substrate, an upper substrate and a liquid crystal layer therebetween. The lower substrate includes, for example, a gate line, a data line, a pixel electrode and a TFT, but is not limited thereto. The upper substrate includes, for example, a common electrode, but is not limited thereto. The LCD creates an electric field at the liquid crystal layer with a voltage applied to the pixel electrode and the common electrode. The created electric field determines an orientation of liquid crystal molecules of the liquid crystal layer, and thus controls polarization of light emitted from a backlight so that an image is displayed on the LCD.

The TFT includes a gate electrode, a source electrode and a drain electrode. An active layer serving as a channel is disposed between the gate electrode and the source and drain electrodes. Light emitted from the backlight enters the active layer through a gate dielectric layer disposed between the gate electrode and the source and drain electrodes. The light entrance to the TFT causes a short-term afterimage because of light leakage, and increases an off-current. The increase in off-current causes a current-voltage curve of the TFT to fluctuate, and thus increases a leakage current, resulting in color degradation, for example. The increase in off-current also causes vertical cross talk.

The light entrance to the TFT is closely associated with a design of the TFT. The TFT may be designed as an I-type in which a source electrode branches from a data line at a right angle, or a U-type in which the source electrode branches from a data line in a U-shape. The source electrode completely overlaps the active layer in the U-type while the source electrode partially overlaps the active layer in the I-type. For this reason, less light enters the U-type TFT than the I-type TFT. Since the aforementioned disadvantages, such as color degradation, occur less in the U-type TFT, most TFTs today are being designed as the U-type.

However, gate-source capacitance (Cgs) fluctuates in the U-type TFT. Accordingly, a kickback voltage changes, causing defects in the display such as afterimages and flickering.

### BRIEF SUMMARY OF THE INVENTION

The present disclosure provides a thin film transistor (“TFT”) configured to reduce light entrance and a liquid crystal display (“LCD”) including the same.

The present disclosure also provides a TFT which can reduce an entrance of light from portions of a source electrode and a drain electrode, which do not overlap a gate electrode, by forming an uneven pattern on at least a portion of the gate electrode corresponding to a boundary with the source electrode and the drain electrode, and an LCD including the TFT.

The present disclosure also provides a TFT that can reduce a light entrance by making light entering an uneven pattern of a gate electrode to be reflected and extinguished by the uneven pattern.

In accordance with an exemplary embodiment, a thin film transistor includes: a gate electrode including an uneven pattern on at least one side thereof; a gate dielectric layer and an active layer disposed on the gate electrode; a source electrode partially overlapping the gate electrode; and a drain electrode separated from the source electrode and partially overlapping the gate electrode.

The gate electrode may have a tapered sectional shape, and the gate electrode may be tapered at an angle ranging from approximately 30° to approximately 70°.

The uneven pattern may be provided entirely on the at least one side of the gate electrode or on a partial portion of the at least one side of the gate electrode.

The uneven pattern may be provided on the partial portion of the at least one side of the gate electrode overlapped with the source electrode and the drain electrode.

The uneven pattern may be provided on the partial portion of the at least one side of the gate electrode overlapped with the source electrode and the drain electrode and on the partial portion of the at least one side of the gate electrode between the source electrode and the drain electrode.

The uneven pattern may include a ridge portion and a furrow portion at least one of which may have an interior angle ranging from approximately 20° to approximately 170°.

Light entering the active layer may be reduced as the interior angle of the uneven pattern is smaller, a distance between the active layer and the furrow portion of the uneven pattern is shorter, and a distance between an extension line of the active layer and a start point of the uneven pattern of the gate electrode is longer.

The source electrode may have an I-shape, and the source electrode may partially overlap the active layer.

The source electrode may have a U-shape. The source electrode may completely overlap the active layer.

In accordance with another exemplary embodiment, a liquid crystal display (LCD) includes: a gate line extending on one substrate in a first direction; a gate electrode protruding from the gate line and including an uneven pattern on at least one side defining the gate electrode; a gate dielectric layer disposed on the substrate including the gate line and the gate electrode; an active layer disposed on the gate dielectric layer placed on the gate electrode; a data line extending in a second direction crossing the gate line; a source electrode protruding from the data line and partially overlapping the gate electrode; a drain electrode partially overlapping the gate electrode and separated from the source electrode; and a pixel electrode electrically connected to the drain electrode.

The gate electrode may have a tapered sectional shape. The gate electrode may be tapered at an angle ranging from approximately 30° to approximately 70°.

The uneven pattern may be provided entirely on the at least one side of the gate electrode or on a partial portion of the at least one side of the gate electrode.

The uneven pattern may include a ridge portion and a furrow portion at least one of which may have an interior angle ranging from approximately 20° to approximately 170°.

The source electrode may include a portion protruding from the data line in a direction substantially perpendicular to the data line, and a portion protruding perpendicularly from the data line. The source electrode may partially overlap the active layer.

The source electrode may have a U-shape. The source electrode may completely overlap the active layer.

Light entering the active layer may be reduced as the interior angle of the uneven pattern is smaller, a distance between the active layer and the furrow portion of the uneven pattern is shorter, and a distance between an extension line of the active layer and a start point of the uneven pattern of the gate electrode is longer.

The LCD may further include: a black matrix disposed on a portion of one surface of another substrate facing the one substrate; a color filter disposed on the one surface of the another substrate at locations excluding the black matrix; and a common electrode disposed on an entire surface of the one surface of the another substrate at locations including the black matrix and the color filter.

### BRIEF DESCRIPTION OF THE DRAWINGS

Exemplary embodiments can be understood in more detail from the following description taken in conjunction with the accompanying drawings, in which:

FIG. 1 is a plan view of an LCD in accordance with an exemplary embodiment;

FIG. 2 is an exploded cross-sectional view taken along line I-I′ of FIG. 1;

FIG. 3 is an exploded cross-sectional view taken along line II-II′ of FIG. 1;

FIG. 4 is an enlarged plan view of a thin film transistor (“TFT”) of the LCD of FIG. 1 in accordance with an exemplary embodiment;

FIG. 5 is a cross-sectional view of a TFT illustrating a light entrance to a related art active layer;

FIG. 6 is a partially enlarged plan view of an uneven pattern of a gate electrode in accordance with an exemplary embodiment;

FIG. 7 is a cross-sectional view taken along line III-III′ of FIG. 6; and

FIGS. 8 through 11 are plan views illustrating various modifications of an uneven pattern of a gate electrode in accordance with exemplary embodiments.

### DETAILED DESCRIPTION OF THE INVENTION

The invention will now be described more fully hereinafter with reference to the accompanying drawings, in which exemplary embodiments of the invention are shown. The present invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including,” when used in this specification, specify the presence of stated features, regions, integers, steps, operations, elements and/or components, but do not preclude the presence or addition of one or more other features, regions, integers, steps, operations, elements, components and/or groups thereof.

Furthermore, relative terms, such as “lower” or “bottom” and “upper” or “top” may be used herein to describe one element's relationship to other elements as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on the “upper” side of the other elements. The exemplary term “lower” can, therefore, encompass both an orientation of “lower” and “upper,” depending upon the particular orientation of the figure. Similarly, if the device in one of the figures were turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning which is consistent with their meaning in the context of the relevant art and the present disclosure, and will not be interpreted in an idealized or overly formal sense unless expressly so defined herein.

Exemplary embodiments of the present invention are described herein with reference to cross section illustrations which are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes which result, for example, from manufacturing. For example, a region illustrated or described as flat may, typically, have rough and/or nonlinear features. Moreover, sharp angles which are illustrated may be rounded. Thus, the regions illustrated in the figures are schematic in nature and their shapes are not intended to illustrate the precise shape of a region and are not intended to limit the scope of the present invention.

Hereinafter, exemplary embodiments of the present invention will be described in further detail with reference to the accompanying drawings.

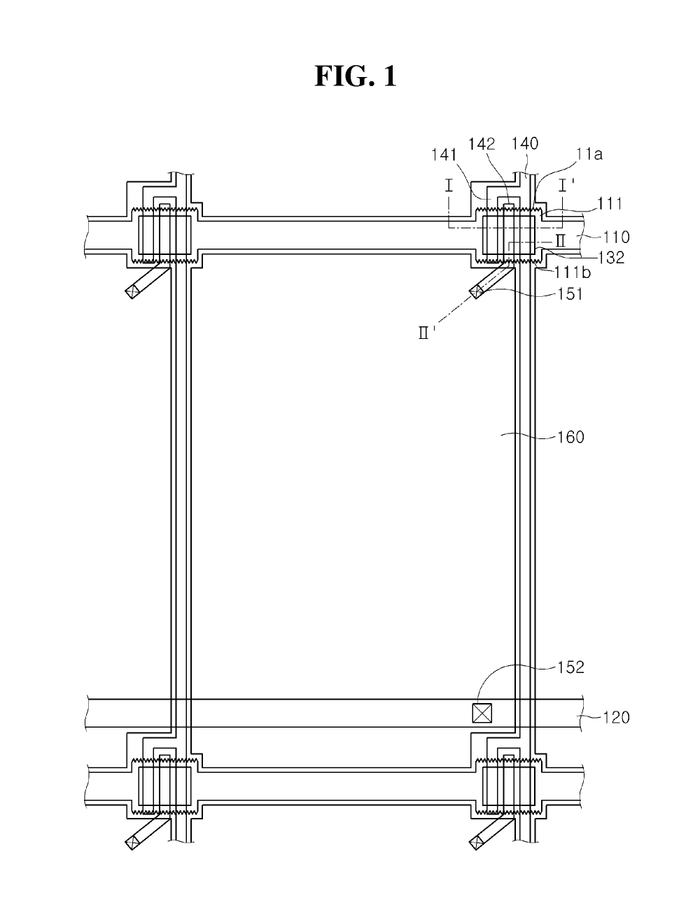

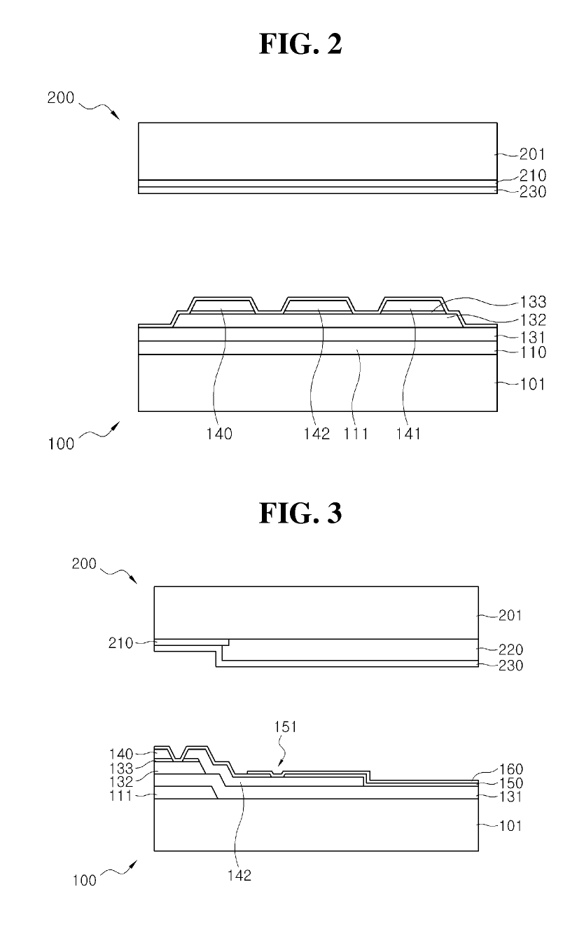

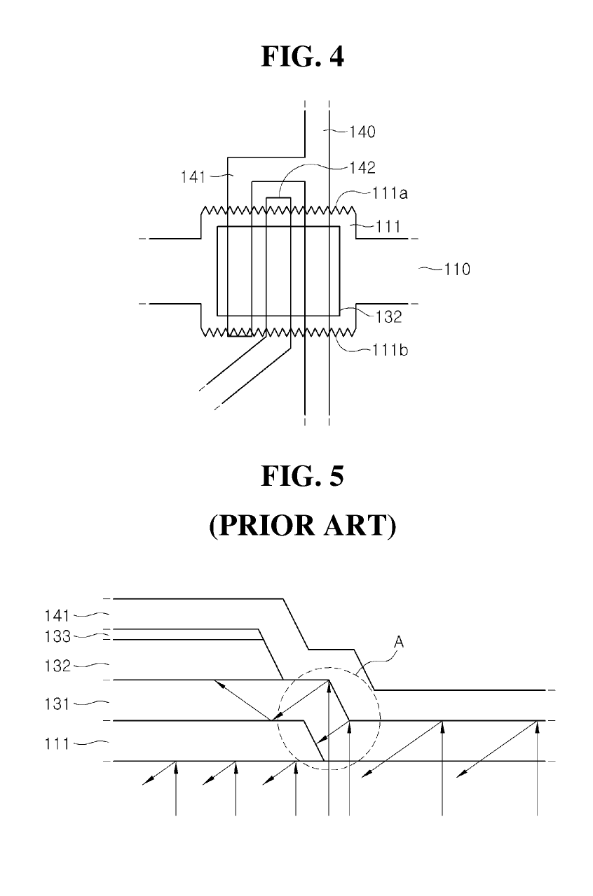

FIG. 1 is a plan view of a liquid crystal display (“LCD”) in accordance with an exemplary embodiment. FIG. 2 is an exploded cross-sectional view taken along line I-I′ of FIG. 1. FIG. 3 is an exploded cross-sectional view taken along line II-II′ of FIG. 1. FIG. 4 is an enlarged plan view of a thin film transistor (“TFT”) of the LCD of FIG. 1 in accordance with an exemplary embodiment.

Referring to FIGS. 1 through 4, the LCD in accordance with an exemplary embodiment includes a lower substrate 100, an upper substrate 200 and a liquid crystal layer (not shown) disposed therebetween. The lower substrate 100 includes a plurality of gate lines 110, a storage electrode line 120, a plurality of data lines 140 and a pixel electrode 160. The upper substrate 200 includes a color filter 220 (FIG. 3) and a common electrode 230.

In the lower substrate 100, the plurality of gate lines 110 extend on a substrate 101 in one direction and are spaced apart from each other at a predetermined interval, and the storage electrode line 120 is disposed substantially parallel to and between the two gate lines 110. The plurality of data lines 140 extend in the other direction crossing the gate lines 110, and are spaced apart from each other at a predetermined interval. The pixel electrode 160 is disposed in a pixel area defined by intersection of the gate lines 110 and the data lines 140. Also, the lower substrate 100 includes a thin film transistor (T) which includes a gate electrode 111, a source electrode 141 and a drain electrode 142. The gate electrode 111 protrudes from the gate line 110 and has two uneven sides which are parallel to the gate line 110. The source electrode 141 protrudes perpendicularly from the data line 140 and partially overlaps the gate electrode 111, and the drain electrode 142 is separated from the data line 140 to be apart from the source electrode 141 and partially overlaps the gate electrode 111.

The gate line 110 extends in one direction, e.g., a horizontal direction, and a portion of the gate line 110 protrudes vertically to form the gate electrode 111, as illustrated in FIGS. 1 and 4. Also, the gate line 110 includes a predetermined uneven pattern, and may protrude vertically from the gate line 110 as the gate line 110 extends horizontally, as illustrated in FIG. 4.

An uneven pattern is formed on at least one side of the gate electrode 111, which is parallel to the gate line 110. As shown, uneven patterns 111a and 111b may be provided at two sides of the gate electrode 111, respectively, which are substantially parallel to the gate line 110. The uneven patterns 111a and 111b may protrude outwardly from the gate electrode 111 or recess inwardly to the gate electrode 111. The size of the uneven patterns 111a and 111b may be adjusted such that the uneven patterns 111a and 111b do not lower an aperture ratio. The uneven patterns 111a and 111b may be formed on an entire length defining the two sides of the gate electrode 111 parallel to the gate line 110, or only at portions of the length of the sides which overlap the source electrode 141 and the drain electrode 142 overlap. Also, the uneven patterns 111a and 111b may be formed at the portion of the length of the sides which overlap the source electrode 141 and the drain electrode 142, and a portion between the source electrode 141 and the drain electrode 142. A section of the gate electrode 111 may be tapered from the bottom to the top (e.g., a tapered sectional shape), and sections of the uneven patterns 111a and 111b may also be tapered. The gate electrode 111 and the uneven patterns 111a and 111b include a tapered elevation at an angle ranging from approximately 30° to approximately 70°, as best illustrated in FIGS. 3 and 5.

The storage electrode line 120 is disposed substantially parallel to and between the two gate lines 110, and may be disposed at a middle portion between the gate lines 110 or may be disposed adjacent to one of the gate lines 110. The storage electrode line 120 and the pixel electrode 160 constitute a storage capacitor in the pixel area, having the gate dielectric layer 131 therebetween. The pixel area is defined by an intersection of the gate line 110 and the data line 140.

The gate line 110 and the storage electrode line 120 may be formed on the same layer by the same process. The gate line 110 and the storage electrode line 120 may be formed of at least one of a plurality of metals including aluminum (Al), copper (Cu), neodymium (Nd), silver (Ag), chrome (Cr), titanium (Ti), tantalum (Ta), molybdenum (Mo), or an alloy of at least one of the foregoing. The gate line 110 and the storage electrode line 120 may have a single layer structure or a multi-layered structure of a plurality of metal layers. In the case of the multi-layered structure, the gate line 110 and the storage electrode line 120 may include two layers having different physical characteristics, e.g., a first layer formed of a material with low specific resistance and a second layer formed of a material with an excellent contact characteristic. The material having low specific resistance may be, e.g., an Al-based, Ag-based or Cu-based metal material in order to reduce signal delay or voltage drop. The material having the excellent contact characteristic may be, e.g., Cr, Mo, Mo alloy, Ta or Ti. The gate electrode 111 and the uneven patterns 111a and 111b may have a bi-layered structure of Mo/Al. If the bi-layered structure of Mo/Al is wet-etched, a tapered angle of approximately 30° is obtained; and in the case of dry-etching, a tapered angle (e.g., elevation taper) of approximately 70° is obtained.

The gate dielectric layer 131 is disposed on the entire substrate 101 including the gate line 110 and the storage electrode line 120. The gate dielectric layer 131 may have a single layer or multi-layered structure using an organic insulating layer such as silicon oxide (“SiO₂”) or silicon nitride (“SiNx”).

An active layer 132 formed of a first semiconductor material is disposed on a predetermined portion of the gate dielectric layer 131 placed on the gate electrode 111. An ohmic contact layer 133 formed of a second semiconductor material is disposed on the active layer 132. The active layer 132 may completely overlap the gate electrode 111 or partially overlap the gate electrode 111. That is, the active layer 132 may have the same size as the gate electrode 111, or may be smaller than the gate electrode 111. The first semiconductor material includes e.g., amorphous silicon, and the second semiconductor material e.g., includes silicide or n+ hydrogenated amorphous silicon heavily doped with n-type impurities.

The data line 140 extends in a direction crossing the gate line 110, e.g., a vertical direction, as illustrated in FIGS. 1 and 4. A portion of the data line 140 protrudes to form the source electrode 141, and the drain electrode 142 is separated from the data line 140 and is spaced apart from the source electrode 141 at a predetermined interval. The source electrode 141 protrudes from the data line 140 in a horizontal direction (hereinafter, referred to as a “horizontal extension portion”), then is bent at a right angle, and protrudes in a vertical direction (hereinafter, referred to as a “vertical extension portion”), as illustrated in FIGS. 1 and 4. That is, the source electrode 141 is formed as in an I-type TFT. The vertical extension portion of the source electrode 141 passes over the gate electrode 111 such that the source electrode 141 partially overlaps the gate electrode 111. The source electrode 141 may have one vertical extension portion or two vertical extension portions. If the source electrode 141 has one vertical extension portion, the gate electrode 111 may be disposed partially under the data line 141, as illustrated. In this case, not only a portion protruding from the data line 140 but also a portion of the data line 140 serves as the source electrode 141. If the source electrode 141 has two vertical extension portions (not shown), the gate electrode 111 may be partially disposed under the two vertical extension portions but not under the data line 140. An interior angle between the horizontal extension portion of the source electrode 141 and the data line 140 may form substantially a right angle. Also, an interior angle between the horizontal extension portion and the vertical extension portion may form substantially a right angle. The drain electrode 142 is formed on the active layer 132 and the ohmic contact layer 133, and spaced apart from the source electrode.

The data line 140 including the source electrode 141 and the drain electrode 142 may be formed of a material used to form the gate line 110 and the storage electrode line 120, and may have a single layer or a multi-layered structure. The data line 140 may have a predetermined uneven pattern.

The thin film transistor (T) charges the pixel electrode 160 with a pixel signal supplied to the data line 140, in response to a signal supplied to the gate line 110. Therefore, the thin film transistor (T) includes the gate electrode 111 connected to the gate line 110, the source electrode 141 connected to the data line 140, and the drain electrode 142 connected to the pixel electrode 160. The gate dielectric layer 131, the active layer 132 and the ohmic contact layer 133 are sequentially disposed between the gate electrode 111 and the source and drain electrodes 141 and 142. The ohmic contact layer 133 may be disposed on the gate dielectric layer 131 excluding a channel portion.

Referring to FIG. 3, a passivation layer 150 is disposed on the entire substrate 101 including the thin film transistor (T) and the data line 140 (FIG. 3). The passivation layer 150 may be formed as an inorganic insulating layer or an organic insulating layer, and may be formed as the inorganic insulating layer including silicon oxide (“SiO₂”) layer or silicon nitride (“SiNx”). A predetermined portion of the passivation layer 150 is removed to form contact holes, i.e., a first contact hole 151 and a second contact hole 152 (FIG. 1). The first contact hole 151 exposes a portion of the drain electrode 142, and the second contact hole 152 exposes a portion of the gate dielectric layer 131 on the storage electrode line 120.

The pixel electrode 160 is disposed on the passivation layer 150. The pixel electrode 160 is formed of a transparent conductive material such as indium tin oxide (“ITO”) or indium zinc oxide (“IZO”). The pixel electrode 150 is connected to the drain electrode 142 through the first contact hole 151. Through the second contact hole 152, the pixel electrode 150 and the storage electrode line 120 form a storage capacitor with the gate dielectric layer 131 disposed therebetween. The pixel electrode 160 may include a cutout (not shown) or a protrusion (not shown) as a domain control unit for adjusting an orientation of liquid crystal molecules of the liquid crystal layer (both not shown). The cutout (not shown) of the pixel electrode 160 may divide the liquid crystal layer into a plurality of domains, together with a cutout (not shown) of the common electrode 230.

The upper substrate 200 includes a black matrix 210, the color filter 220 and the common electrode 230 disposed on a second insulating substrate 201.

The black matrix 210 is disposed on the upper substrate, corresponding to areas excluding the pixel area, e.g., corresponding to the gate line 110, the data line 140 and the thin film transistor (T) of the lower substrate 200. The black matrix 210 serves to prevent light leakage to the areas excluding the pixel area, and light interference between adjacent pixel areas. The black matrix 210 is formed of a photosensitive organic material with a black pigment added. For example, carbon black or titanium oxide is used as the black pigment.

The color filter 220 includes red (R), green (G) and blue (B) color filters which are arranged repetitively, and the black matrix 210 serves as a boundary of the R, G and B color filters. The color filter 220 serves to impart colors to light having passed through the liquid crystal layer (not shown) from a light source (not shown), and may be formed of a photosensitive organic material.

The common electrode 230 is formed of a transparent conductive material such as ITO and IZO, and is disposed on the second insulating substrate 201 including the black matrix 210 and the color filter 220. A cutout (not shown) may be formed in the common electrode 230, as discussed above. The cutout (not shown) of the common electrode 230 serves to divide the liquid crystal layer into a plurality of domains, together with the cutout (not shown) of the pixel electrode 160.

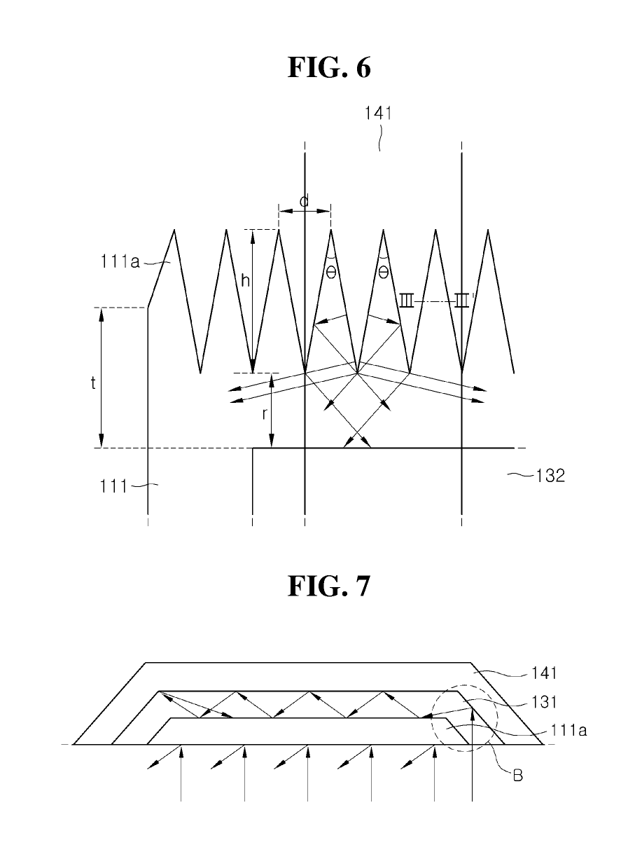

In accordance with an exemplary embodiment, the uneven patterns 111a and 111b are formed on at least one side of the gate electrode 111 (e.g., one of two opposing sides of the gate electrode extending in a same direction as opposing sides defining a width of the gate line), so that the light entrance to the thin film transistor (T) is reduced. This will now be described in comparison with the related art with reference to FIG. 5. FIG. 5 is a cross-sectional view illustrating a light entrance in a related art TFT including a gate electrode not having an uneven pattern on either side. FIG. 6 is a partially enlarged plan view of a TFT including a gate electrode with an uneven pattern in accordance with an exemplary embodiment. FIG. 7 is a cross-sectional view taken along line III-III′ of FIG. 6. That is, FIG. 7 is a cross-sectional view of a single protrusion defining one uneven pattern 111a in a horizontal direction with respect to FIG. 6.

Referring to FIG. 5, light emitted from a backlight (not shown) is reflected by a gate electrode 111, a source electrode 141 and a drain electrode (not shown) which are formed of a metal material. Light reflected from areas of the source electrode 141 and the drain electrode adjacent to the gate electrode 111 without overlapping the gate electrode 111, i.e., an inclined area (A) of the source electrode 141 and the drain electrode, partially enters an active layer 132, reflected between the gate electrode 111 and the source electrode 141 and drain electrode. The light entering the active layer 132 is extinguished more as the number of times that the light is reflected increases. Accordingly, the light entering the active layer 132 can be reduced by increasing a distance between side surfaces of the active layer 132 and the gate electrode 111. To this end, an area of the active layer 132 must be decreased or an area of the gate electrode 111 must be increased. The decrease in area of the active layer 132 causes a channel area to decrease, and an increase in area of the gate electrode 111 lowers an aperture ratio.

In contrast, in accordance with an exemplary embodiment, an uneven pattern is formed on at least one side of the gate electrode 111 defining a nonplanar surface side of the gate electrode 111. That is, the uneven patterns 111a and 111b may be formed at one side and the other opposite side of the gate electrode 111, thereby reducing incident light. In such a manner, light entering the active layer 132 can be reduced without decreasing an aperture ratio. This will now be described with reference to FIGS. 6 and 7.

Referring to FIGS. 6 and 7, light emitted from a backlight is reflected by one portion (B) of the source electrode 141 (FIG. 7) and the drain electrode 142 (FIG. 4) which do not overlap the uneven pattern 111a and is incident on a top surface of the uneven pattern 111a. The light incident on the top surface of the uneven pattern 111a is reflected between the top surface of the uneven pattern 111a and a bottom surface of the source electrode 141, and between the top surface of the uneven pattern 111a and a top surface of the drain electrode 142 (FIG. 4). Since the uneven pattern 111a is tapered from the bottom to the top with respect to FIG. 7, light is repetitively reflected without being leaked to the outside of the uneven pattern 111a. The repetitive reflection extinguishes light. However, from a portion of the uneven pattern 111a with a wide width, light enters the active layer 132 at half the interior angle θ defined by opposite sides defining a single protrusion defining one uneven pattern 111a.

In FIG. 6, h denotes a height between a ridge and a furrow of the uneven pattern 111a of the gate electrode 111, i.e., a height between an upper vertex and a lower vertex, r denotes a distance between the active layer 132 and the furrow, i.e., the lower vertex of the uneven pattern 111a, d denotes a distance between two contiguous ridges of the uneven pattern 111a, i.e., between upper vertexes, t denotes a distance between an extension line of the active layer 132 and a virtual gate electrode 111 having no uneven pattern 111a, and θ denotes an interior angle defined by an upper vertex of the uneven pattern 111a. If the intensity of light entering the active layer 132 is Iₒ in the case where the uneven pattern is not formed, light is incident onto the active layer 132 at an angle of θ/2, and thus the intensity of light leaked from the uneven pattern 111a is expressed as Equation 1 below:

2×Iₒ sin(θ/2)/(2/sin(θ/2)=Iₒ sin²(θ/2) Equation 1

Also, a distance at which light is incident at an angle of θ/2 is expressed as Equation 2 below:

r/sin(θ/2) Equation 2

Accordingly, using Equations 1 and 2, the total intensity of light incident to the active layer 132 of the thin film transistor is expressed as Equation 3 below:

$$\frac{t}{r} \times {I}_{o} {sin}^{3} ( \frac{θ}{2} ) \qquad Equation 3$$

As one example, if the height h of the uneven pattern 111a of the gate electrode 111 is 4 μm, the distance r between the active layer 132 and the lower vertex of the uneven pattern 111a is 2 μm, a width of the uneven pattern 111a, i.e., the distance d between the upper vertex and the lower vertex of the uneven pattern 111a is 2 μm, the distance t between the extension line of the active layer 132 and a start point of the uneven pattern 111a at one surface of the gate electrode 111 is 4 μm, and the interior angle θ of the uneven pattern 111a is 28°, 0.028 Iₒ is calculated by Equation 3. Thus, as compared to the related art in which the uneven pattern 111a is not formed, light entering the active layer 132 is reduced by 97.2%. As another example, if the distance d between the upper vertex and the lower vertex is changed to 3 μm and the interior angle θ of the uneven pattern 111a is changed to 41° while other conditions are the same as in the above one example, 0.043 Iₒ is calculated by Equation 3. Consequently, as compared to the related art in which the uneven pattern 111a is not formed, light incident to the active layer 132 is reduced by 95.7%. In those two cases, since the uneven pattern 111a is protruded from and recessed into the gate electrode 111, the an aperture ratio is maintained at the same level as that in the case where the uneven pattern 111a is not formed.

However, if an aperture ratio is reduced by the uneven pattern 111a, i.e., if the uneven pattern 111a is protruded outwardly from the gate electrode 111, light entering the active layer 132 can be reduced as compared to the case where the same aperture ratio is maintained. For example, if the distance r between the active layer 132 and the lower vertex of the uneven pattern 111a is changed to 4 μm, the distance t between the extension line of the active layer 132 and the start point of the uneven pattern 111a at one side of the gate electrode is changed to 4 μm, and the interior angle θ of the uneven pattern 111a is changed to 28° under the above-mentioned conditions, 0.014 Iₒ is calculated by Equation 3. Thus, light entering the active layer 132 is reduced by 98.6% as compared to the related art where the uneven pattern 111a is not formed. As another example, if the distance r between the active layer 132 and the lower vertex of the uneven pattern 111a is changed to 4 μm, the distance d between the upper vertex and the lower vertex of the uneven pattern 111a is changed to 3 μm, and the interior angle θ of the uneven pattern 111a is changed to 41°, 0.021Iₒ is calculated by Equation 3. Thus, light entering the active layer 132 is reduced by 97.9% as compared to the related art where the uneven pattern 111a is not formed.

As for the uneven pattern 111a of the gate electrode 111 in accordance with an exemplary embodiment, in the case where the distance r between the active layer 132 and the lower vertex of the uneven pattern 111a is the same as the distance t between the extension line of the active layer 132 and the start point of the uneven pattern 111a at one side of the gate electrode 111, light entering the active layer 132 can be reduced as compared to the related art when the angle θ of the uneven pattern 111a is 170° or less. Also, as the angle θ of the uneven pattern 111a is smaller and the distance r between the active layer 132 and the lower vertex of the uneven pattern 111a is longer, light entering the active layer 132 can be reduced. Further, as the distance t between the extension line of the active layer 132 and the start point of the uneven pattern 111a at one side of the gate electrode 111 is shorter, light entering the active layer 132 can be reduced. The angle θ of the uneven pattern 111a determines the height h of the uneven pattern 111a and the distance d between adjacent upper vertexes of the uneven pattern 111a. That is, as the angle θ of the uneven pattern 111a is reduced, the height h of the uneven pattern 111a is increased and the distance d between the adjacent upper vertexes of the uneven pattern 111a is reduced. In contrast, if the angle θ of the uneven pattern 111a is increased, the height h of the uneven pattern 111a is reduced, and the distance d between the adjacent upper vertexes of the uneven pattern 111a is increased. For this reason, the height h of the uneven pattern 111a and the distance d between the upper vertexes of the uneven pattern 111a are not used in the above equations for calculating intensity of light entering the active layer 132.

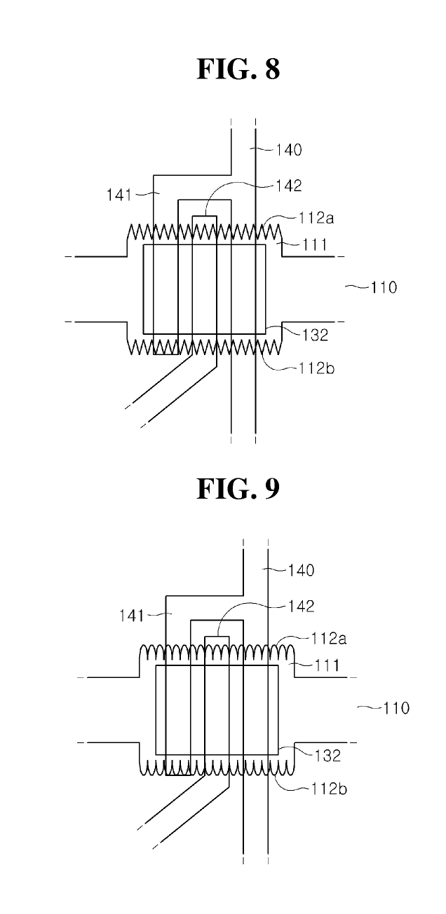

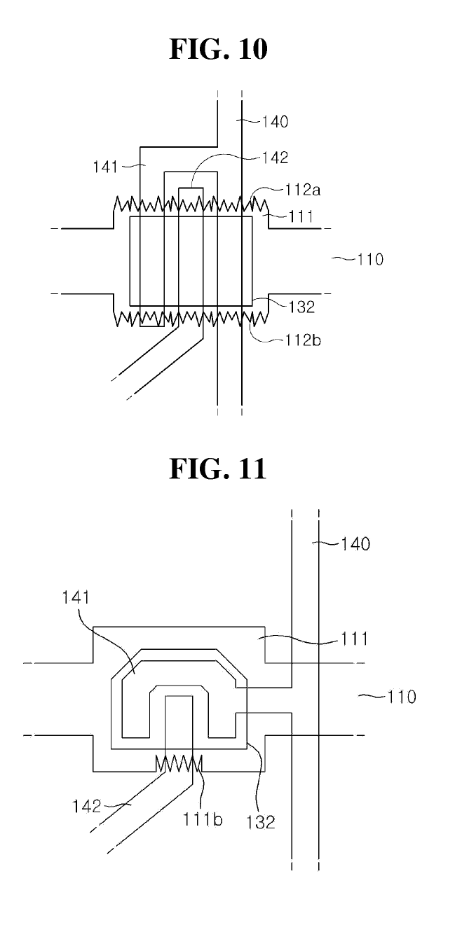

The uneven pattern 111a of the gate electrode 111 may be formed in various shapes. As shown in FIG. 8, a dense uneven pattern 112a of triangle shapes may be formed by reducing the angle θ of the uneven pattern 111a. Alternatively, an uneven pattern 112a of oval shapes may be formed as shown in FIG. 9. Alternatively, as shown in FIG. 10, an uneven pattern 112a of irregular triangle shapes (e.g., non-uniform triangle shapes) may be formed.

Also, the gate electrode including the uneven pattern may be applied not only to the I-type thin film transistor but also to a U-type thin film transistor. As shown in FIG. 11, the source electrode 141 has a U-shape. Even if the source electrode 141 entirely overlaps the active layer 132, a light entrance may occur at one area of the drain electrode 142 disposed in the source electrode 141 and not overlapping the gate electrode 111. Therefore, an uneven pattern 111b may be formed at a portion defining one side of the gate electrode 111 placed under the drain electrode 142 or the entire side of the gate electrode 111 placed under the drain electrode 142. Even in this case, the uneven pattern 111b may have various shapes which can prevent the light entrance, such as regular triangles, irregular triangles, or ovals, for example, but is not limited thereto.

In accordance with an exemplary embodiment, the uneven pattern is formed on at least one side defining the gate electrode, which serve as a boundary with the source electrode and the drain electrode of the thin film transistor. Light entering the uneven pattern formed on at least one side of the gate electrode is reflected by the uneven pattern and extinguished. Accordingly, light entering an active layer is reduced, so that short-term afterimages and an increase in off-current caused by light leakage can be prevented. Consequently, characteristics of an LCD, particularly, display characteristics can be improved.

Although the thin film transistor and a liquid crystal display including the same have been described with reference to the specific exemplary embodiments, they are not limited thereto. Therefore, it will be readily understood by those skilled in the art that various modifications and changes can be made thereto without departing from the spirit and scope of the present invention defined by the appended claims.

What is claimed is:

1. A thin film transistor comprising:
a gate electrode including an uneven pattern on at least one side thereof;
a gate dielectric layer and an active layer disposed on the gate electrode;
a source electrode partially overlapping the gate electrode; and
a drain electrode separated from the source electrode and partially overlapping the gate electrode.

2. The thin film transistor of claim 1, wherein the gate electrode has a tapered sectional shape.

3. The thin film transistor of claim 2, wherein the gate electrode is tapered at an angle ranging from approximately 30° to approximately 70°.

4. The thin film transistor of claim 3, wherein the uneven pattern is provided on a partial portion of the at least one side of the gate electrode.

5. The thin film transistor of claim 4, wherein the uneven pattern is provided on the partial portion of the at least one side of the gate electrode overlapped with the source electrode and the drain electrode.

6. The thin film transistor of claim 4, wherein the uneven pattern is provided on the partial portion of the at least one side of the gate electrode overlapped with the source electrode and the drain electrode and on the partial portion of the at least one side of the gate electrode between the source electrode and the drain electrode.

7. The thin film transistor of claim 6, wherein the uneven pattern comprises a ridge portion and a furrow portion at least one of which has an interior angle ranging from approximately 20° to approximately 170°.

8. The thin film transistor of claim 7, wherein the uneven pattern reflects and extinguishes light entering the active layer as the interior angle of the uneven pattern is smaller, a distance between the active layer and the furrow portion of the uneven pattern is shorter, and a distance between an extension line of the active layer and a start point of the uneven pattern of the gate electrode is longer.

9. The thin film transistor of claim 1, wherein the source electrode branches from a data line and extends parallel to the data line.

10. The thin film transistor of claim 9, wherein the source electrode partially overlaps the active layer.

11. The thin film transistor of claim 1, wherein the source electrode has a U-shape.

12. The thin film transistor of claim 11, wherein the source electrode completely overlaps the active layer.

13. The thin film transistor of claim 1, wherein the gate electrode, the active layer, and a data line connected with the source electrode are overlapped with each other.

14. A liquid crystal display comprising:
a gate line extending on one substrate in a first direction;
a gate electrode protruding from the gate line and comprising an uneven pattern on at least one side defining the gate electrode;
a gate dielectric layer disposed on the substrate including the gate line and the gate electrode;
an active layer disposed on the gate dielectric layer placed on the gate electrode;
a data line extending in a second direction crossing the gate line;
a source electrode protruding from the data line and partially overlapping the gate electrode;
a drain electrode partially overlapping the gate electrode and separated from the source electrode; and
a pixel electrode electrically connected to the drain electrode.

15. The liquid crystal display of claim 14, wherein the gate electrode has a tapered sectional shape.

16. The liquid crystal display of claim 15, wherein the gate electrode is tapered at an angle ranging from approximately 30° to approximately 70°.

17. The liquid crystal display of claim 16, wherein the uneven pattern is provided on a partial portion of the at least one side of the gate electrode.

18. The liquid crystal display of claim 17, wherein the uneven pattern comprises a ridge portion and a furrow portion at least one of which has an interior angle ranging from approximately 20° to approximately 170°.

19. The liquid crystal display of claim 18, wherein the source electrode comprises a portion protruding from the data line in a direction substantially perpendicular to the data line, and a portion protruding perpendicularly from the portion protruding from the date line.

20. The liquid crystal display of claim 19, wherein the source electrode partially overlaps the active layer.

21. The liquid crystal display of claim 18, wherein the source electrode has a U-shape.

22. The liquid crystal display of claim 21, wherein the source electrode completely overlaps the active layer.

23. The liquid crystal display of claim 18, wherein the uneven pattern reflects and extinguishes light entering the active layer as the interior angle of the uneven pattern is smaller, a distance between the active layer and the furrow portion of the uneven pattern is shorter, and a distance between an extension line of the active layer and a start point of the uneven pattern of the gate electrode is longer.

24. The liquid crystal display of claim 14, wherein the gate electrode, the active layer, and the data line are overlapped with each other.

25. The liquid crystal display of claim 14, further comprising:
a black matrix disposed on a portion of one surface of another substrate facing the one substrate;
a color filter disposed on the one surface of the another substrate at locations excluding the black matrix; and
a common electrode disposed on an entire surface of the one surface of the another substrate including the black matrix and the color filter.
